(19) United States
(12) Patent Application Publication
(10) Pub. No.: US 2025/0299928 A1
(43) Pub. Date: Sep. 25, 2025

(54) PLASMA PROCESSING METHOD

(71) Applicant: Hitachi High-Tech Corporation, Minato-ku, Tokyo (JP)

(72) Inventors: Yusuke NAKATANI, Tokyo (JP); Yasushi SONODA, Tokyo (JP); Motohiro TANAKA, Tokyo (JP)

(21) Appl. No.: 18/691,760

(22) PCT Filed: Dec. 13, 2022
(86) PCT No.: PCT/JP2022/045949

§ 371 Date: Mar. 13, 2024

(51) Int. Cl. H01J 37/32; H01L 21/3065

(52) U.S. Cl. CPC H01J 37/32449; H01J 37/32678; H01J 2237/3341; H01L 21/3065

(57) ABSTRACT

To independently control etching shapes of sparse and dense pattern portions in a single wafer and enable uniform etching processing regardless of whether the pattern is dense or sparse, a plasma processing method is characterized by including a first step of performing reactive ion etching using gas resulting in a tapered shape, and a second step of performing radical etching, characterized in that the first step and the second step are alternately repeated for a predetermined number of times, and a time of the first step is shorter than a time of the second step.

### TECHNICAL FIELD

The present invention relates to a plasma processing method.

### BACKGROUND ART

Due to recent complication and sophistication of three-dimensional shapes of semiconductor devices, there has been a growing demand for uniform etching for sparse and dense pattern portions coexisting in a single wafer.

With conventional reactive ion etching (RIE), the etching performed for a dense pattern portion to obtain a vertical shape often results in a tapered shape, due to a large etching-inhibiting effect in the sparse portion including a large amount of reaction products attributable to a large etched area. To achieve the uniform etching regardless of whether the pattern is dense or sparse, the etching shapes need to be controlled independently in the dense portion and in the sparse portion.

PTL 1 proposes a technique of implementing, in an etching step to form a groove in a semiconductor substrate, a first step of performing the etching under a high etching rate condition immediately after the etching starts, and a second step of then performing the etching under a low etching rate condition.

PTL 2 proposes a technique of repeating, for a plurality of times, an etching step of forming roughness on an etching surface of a substrate by mainly ion-based anisotropic etching, and a step, after the preceding step, of removing the roughness as a result of the preceding step by mainly radical-based isotropic etching of non-cumulative gas on the substrate.

### CITATION LIST

### Patent Literature

PTL 1: JP2015-153804A

PTL 2: JPH03-093224A

### SUMMARY OF INVENTION

### Technical Problem

To achieve the uniform etching for sparse and dense pattern portions in a single wafer, the etching shapes need to be controlled independently in the dense portion and in the sparse portion.

The technique described in PTL 1 shares the same task as the present invention of suppressing the variation in the etching amount between the dense and sparse patterns, but employs a different solution.

The technique described in PTL 2 repeats the ion-based etching and the radical-based etching to achieve both the verticalness and smoothness of the patterns as a result of the etchings, and is not related to the independent control on the etching shapes of the dense and the sparse pattern portions.

The present invention overcomes the problem of the conventional techniques as described above, and provides a plasma processing method enabling etching processing to be uniformly performed on dense and sparse pattern portions in a single wafer.

### Solution to Problem

A plasma processing method of the present invention to solve the problem described above is characterized by including a first step of performing reactive ion etching using gas resulting in a tapered shape, and a second step of performing radical etching, characterized in that the first step and the second step are alternately repeated for a predetermined number of times, and a time of the first step is shorter than a time of the second step.

### Advantageous Effects of Invention

With the present invention, the etching shapes of sparse and dense pattern portions in a single wafer can be independently controlled, and the dense and the sparse portions can be uniformly etched.

### BRIEF DESCRIPTION OF DRAWINGS

FIG. 1 is a vertical cross-sectional view schematically illustrating a plasma etching apparatus according to Embodiment 1 of the present invention.

FIG. 2 is a plan view illustrating a shielding plate of the plasma etching apparatus according to Embodiment 1 of the present invention.

FIG. 3A is a diagram illustrating current, from a DC coil current power supply according to Embodiment 1 of the present invention, for setting an ECR region to be the center.

FIG. 3B is a diagram illustrating current, from the DC coil current power supply according to Embodiment 1 of the present invention, for setting the ECR region to be the center.

FIG. 4A is a diagram illustrating current, from an AC coil current power supply, for moving the ECR region up and down with respect to the ion shielding plate, with the ECR region in FIG. 3A serving as an initial setting position.

FIG. 4B is a diagram illustrating current, from the AC coil current power supply, for moving the ECR region up and down with respect to the ion shielding plate, with the ECR region in FIG. 3B serving as the initial setting position.

FIG. 5 is a schematic view of etching shapes indicating that the etching shapes of dense and sparse portions can be independently controlled, through control on RIE time ratio according to Embodiment 1 of the present invention.

FIG. 6 is a graph illustrating that a taper angle can be made equal between the dense and the sparse portions, through the control on the RIE time ratio according to Embodiment 1 of the present invention.

FIG. 7 is a flowchart illustrating a processing flow of a plasma etching method according to Embodiment 1 of the present invention.

FIG. 8 is a vertical cross-sectional view schematically illustrating a plasma etching apparatus according to a modification of Embodiment 1 of the present invention.

FIG. 9A is a diagram illustrating current, from a DC coil current power supply according to the modification of Embodiment 1 of the present invention, for setting an ECR region corresponding to a center frequency of a variable frequency electromagnetic wave generating power supply.

FIG. 9B is a diagram illustrating current, from the DC coil current power supply according to the modification of Embodiment 1 of the present invention, for setting the ECR region corresponding to the center frequency of the variable frequency electromagnetic wave generating power supply.

FIG. 10A is a diagram illustrating current, from an AC coil current power supply, for moving the ECR region up and down with respect to the ion shielding plate with the ECR region corresponding to the center frequency set in FIG. 9A set as the center, by changing the frequency of the variable frequency electromagnetic wave generating power supply.

FIG. 10B is a diagram illustrating current, from the AC coil current power supply, for moving the ECR region up and down with respect to the ion shielding plate with the ECR region corresponding to the center frequency set in FIG. 9B set as the center, by changing the frequency of the variable frequency electromagnetic wave generating power supply.

FIG. 11 is a vertical cross-sectional view schematically illustrating a plasma etching apparatus according to Embodiment 2 of the present invention.

FIG. 12 is a flowchart illustrating a processing flow of a plasma etching method according to Embodiment 2 of the present invention.

### DESCRIPTION OF EMBODIMENTS

The present invention uses a plasma processing apparatus including a gas system characterized in that a tapered shape is obtained by etching with RIE, and the etching also proceeds with radical etching performed with ions shielded in the same gas system, to enable uniform etching of dense and sparse pattern portions in a single water, through repetitive execution of the processing by RIE and the processing by the radial etching under control.

Furthermore, the present invention uses a plasma processing apparatus including a gas system characterized in that a tapered shape is obtained by etching with RIE, and the etching also proceeds with radical etching performed with ions shielded in the same gas system, to perform control on an RIE time ratio (a ratio of the RIE processing time to the total processing time of the RIE and the radical etching) to obtain a desired etching shape, and repetitive execution of the RIE and the radical etching for a predetermined number of times, to enable independent control on the etching shapes of the dense and the sparse pattern portions in a single wafer, thereby enabling uniform etching of the dense and the sparse portions.

Embodiments of the present invention will be described in detail below based on the drawings. In the description of the embodiments, components with the same function are denoted by the same reference numerals over the entire drawings, and redundant description thereof will be omitted in principle.

It should be noted that the interpretation of the present invention is not limited to what is described in the embodiments below. A person skilled in the art will easily understand that the specific configuration may be changed without departing from the idea and the gist of the present invention.

### Embodiment 1

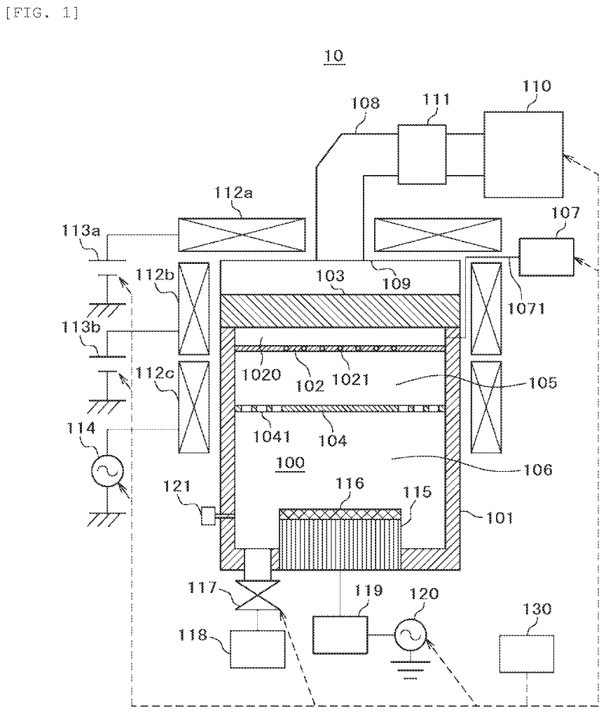

FIG. 1 is a vertical cross-sectional view schematically illustrating an overall configuration of a plasma processing apparatus according to the present embodiment. A plasma processing apparatus 10 illustrated in FIG. 1 includes a processing chamber 100 formed in a vacuum container 101. In an upper portion of the vacuum container 101, a shower plate 102 for introducing etching gas into the processing chamber 100 in the vacuum container 101, a dielectric window 103 for airtightly sealing the upper portion of the processing chamber 100, and an ion shielding plate 104 are provided to configure the processing chamber 100.

A gas supply device 107 is connected to a region 1020 between the shower plate 102 and the dielectric window 103 through a gas supply pipe 1071, and supplies gas for performing plasma etching processing. A plurality of holes 1021 with a small diameter, through which the gas supplied to the region 1020 flows toward the processing chamber 100, are formed in the shower plate 102. A vacuum exhaust device 118 is connected to the vacuum container 101 via a pressure adjustment valve 117, to control the pressure in the processing chamber 100. The pressure in the processing chamber 100 is measured by a pressure gauge 121.

A waveguide 108 (or an antenna) that radiates electromagnetic waves is provided above the dielectric window 103, to transmit plasma generation power to the processing chamber 100. To the waveguide 108 (or the antenna), electromagnetic waves oscillated from an electromagnetic wave generating power supply (also referred to as a radio-frequency power supply) 110 are transmitted through an electromagnetic wave matching box 111. The frequency of radio-frequency current output from the electromagnetic wave generating power supply 110 is a constant frequency in Embodiment 1. A cavity resonator 109 is disposed to form, using the electromagnetic waves propagated from the waveguide 108, a standing wave under a certain mode in the processing chamber 100. The frequency of the electromagnetic waves is not particularly limited, and the waves are microwaves at 2.45 GHz in the present embodiment.

Magnetic field generation coils 112a, 112b, and 112c are provided in an outer circumference portion of the processing chamber 100. DC coil current power supplies 113a and 113b are connected to the magnetic field generation coils 112a and 112b to control the current therein. An AC coil current power supply 114 is connected to the magnetic field generation coil 112c. The magnetic field generation coils 112a and 112b are driven by direct current output from the DC coil current power supplies 113a and 113b. The magnetic field generation coil 112c is driven by alternating current output from the AC coil current power supply 114.

The magnetic field generation coils 112, the DC coil current power supplies 113a and 113b, and the AC coil current power supply 114 may be referred to as a magnetic field forming mechanism. The magnetic field generation coils 112a and 112b may be referred to as a first coil. The magnetic field generation coil 112c may be referred to as a second coil.

Plasma is generated in the processing chamber 100 through electron cyclotron resonance (ECR) between the power oscillated by the electromagnetic wave generating power supply 110 and a magnetic field formed by the magnetic field generation coil 112.

In a lower portion of the processing chamber 100 facing the ion shielding plate 104, a substrate electrode 115 also serving as a placement stage (also referred to as a sample stage) for a sample (semiconductor substrate) 116 is disposed. A radio-frequency power supply 120 is connected to the substrate electrode 115 via a radio-frequency matching box 119. With radio-frequency power supplied from the radio-frequency power supply 120 connected to the substrate electrode 115, negative voltage generally known as self-bias is generated on the substrate electrode 115. Etching processing is performed on the sample 116, by ions in the plasma accelerated by the self-bias and being perpendicularly incident on the sample 116 placed on the substrate electrode 115.

The ion shielding plate 104 divides the internal space of the processing chamber 100 into upper and lower regions. In this specification, in the internal space of the processing chamber 100, a region more on the upper side than the ion shielding plate 104 and between the ion shielding plate 104 and the shower plate 102 is referred to as a first region or a radical region 105, and a region more on the lower side than the ion shielding plate 104 where the substrate electrode 115 is disposed is referred to as a second region or a reactive ion etching (RIE) region 106. The magnetic field generation coils 112a and 112b are disposed more on the upper side than the ion shielding plate 104. The magnetic field generation coil 112c is disposed on the lower side of the magnetic field generation coils 112a and 112b, and in the vicinity of the ion shielding plate 104.

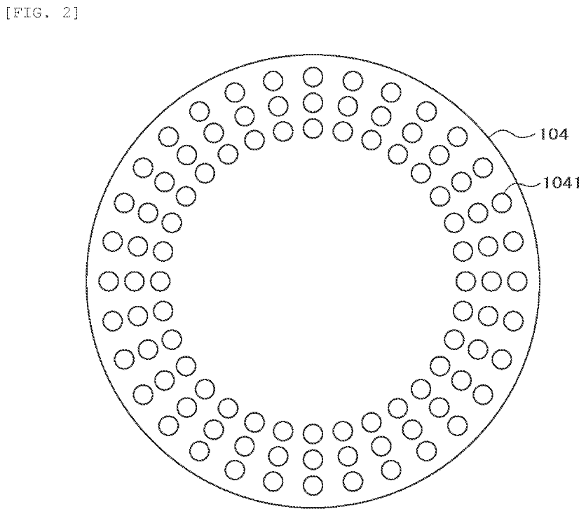

As illustrated in FIG. 2, the ion shielding plate 104 has through holes 1041 of the same diameter uniformly arranged in the outer circumference portion. In the present embodiment, this “uniformly” means that the through holes 1041 with the center points on the circumferences of a plurality of respective concentric circles with an equal difference in diameter (including a case of zero radius) are arranged at an equal pitch in the circumferential direction.

When the plasma is generated in the radical region 105, the ions generated in the plasma are confined in the radical region 105 by the ion shielding plate 104. On the other hand, radicals generated in the plasma are diffused inside the radical region 105, and some of the radicals reach the RIE region 106 through the through holes 1041 of the ion shielding plate 104.

To cause ECR with the electromagnetic waves at 2.45 GHz and generate the plasma, a magnetic field with a magnetic flux density of 0.0875 tesla (T) is required. A region in the processing chamber 100 where the magnetic flux density is 0.0875 T is set to as a position of the ECR region. To generate the high-intensity magnetic field, the magnetic field generation coils 112 with self-inductance of 100 to 1000 mH are used, and the DC coil current power supplies 113a and 113b, and the AC coil current power supply 114 are capable of supplying current of about 10 to 60 A. By controlling the values of current supplied from the plurality of DC coil current power supplies 113a and 113b and the AC coil current power supply 114 to the magnetic field generation coils 112a to 112c respectively connected thereto, the plasma generation position can be moved with respect to the sample 116 with the position of the ECR region in the processing chamber 100 controlled precisely.

The magnetic field generation coils 112a and 112b are positioned more on the upper side than the ion shielding plate 104, and thus the intensity of the magnetic field generated by these magnetic field generation coils 112a and 112b is higher in the radical region 105 close to the magnetic field generation coils 112a and 112b, than in the RIE region 106. This is because, for propagating the electromagnetic waves to the ECR region where the plasma is generated, the magnetic field is preferably set to have the intensity decreasing toward the ECR region from the incident direction of the electromagnetic waves. Thus, the magnetic field increases in the direction of the waveguide 108 as viewed from the ECR region, that is, in the direction of the radical region 105 as viewed from the RIE region 106.

As described above, the processing chamber 100 has the ion shielding plate 104 provided between the shower plate 102 and the substrate electrode 115 serving as the placement stage for the sample 116, and is divided into two regions that are the radical region 105 more on the upper side than the ion shielding plate 104 and the RIE region 106 more on the lower side than the ion shielding plate 104.

When plasma is generated with the position of the ECR region set to be in the radical region 105, since the ion shielding plate 104 is disposed between the sample 116 and the plasma, ions in the plasma generated in a nearly center region in the radical region 105 are captured by the magnetic field in the ECR region so as to to be diffused and are shielded at nearly the center portion of the ion shielding plate 104 to be confined inside the radical region 105. As a result, the ions from the plasma do not reach the sample 116 on the RIE region 106 side. In contrast, radicals generated in the radical region 105 are diffused in the radical region 105 without being captured by the magnetic field in the ECR region, and some of the radicals pass through the large number of through holes 1041 formed in the circumference of the ion shielding plate 104. With the radicals thus supplied to the RIE region 106 side, the sample 116 is plasma-processed through radical etching (isotropic etching).

On the other hand, when plasma is generated with the position of the ECR region set to be in the RIE region 106, since there is no shield between the plasma generated in the ECR region and the sample 116, both ions and radicals from the plasma are supplied to the sample 116, and the sample 116 is plasma-processed through RIE (anisotropic etching).

The gas supply device 107, the pressure adjustment valve 117, the electromagnetic wave generating power supply 110, the DC coil current power supplies 113a and 113b, the AC coil current power supply 114, and the radio-frequency power supply 120 are connected to a control unit 130 that controls the plasma processing apparatus 10 in accordance with process conditions. For process conditions including a plurality of plasma processing steps, the control unit 130 controls apparatus parameters sequentially according to the processing steps to perform etching processing on the sample 116. In addition, information on the inner pressure of the processing chamber 100 measured by the pressure gauge 121 is sent to the control unit 130, and is used for control on process conditions including a plurality of plasma processing steps.

In the present embodiment, when the position of the ECR region is set to be in the radical region 105 on the upper side of the ion shielding plate 104, the radicals are mainly supplied to the sample 116. When the position of the ECR region is set to be in the RIE region 106 on the lower side of the ion shielding plate 104, the radicals and the ions are both supplied to the sample 116. Based on this, the position of the ECR region is set to be in these two regions periodically, whereby the reactive ion etching is performed with the amounts of ions and radicals supplied to the sample 116 controlled.

With normal RIE, the plasma is generated in a region corresponding to the RIE region 106 over the entire processing time. In the present embodiment on the other hand, switching between the plasma generation in the RIE region 106 and the plasma generation in the radical region 105 is performed, so that there can be a time when the radicals are mainly supplied to the sample 116, in addition to a time when the ions and the radicals are both supplied to the sample 116. With the plasma generation region switched periodically between the RIE region 106 and the radical region 105, the RIE as a whole can be performed with the amounts of ions and radicals supplied to the sample 116 respectively reduced and increased.

The ions are mainly supplied during the time when the plasma is generated in the RIE region 106. Thus, the amount of ions supplied to the sample 116 is proportional to the ratio of time when the position of the ECR region is set to be in the RIE region 106 to the time of one period during which the position of the ECR region is periodically switched between the radical region 105 and the RIE region 106 sandwiching the ion shielding plate 104.

When the ratio of the time when the position of the ECR region is set to be in the RIE region 106 to the time of one period during which the ECR region is switched is increased, the ratio of the ions incident on the sample 116 is increased. When the ratio of the time when the position of the ECR region is set to be in the radical region 105 is increased, the ratio of the radicals incident on the sample 116 is increased. The amounts of the ions and the radicals incident on the sample 116 can be changed by thus changing the ratio between the time when the position of the ECR region is set to be in the RIE region 106 and the time when the position of the ECR region is set to be in the radical region 105 in one period during which the ECR region is switched.

The control of periodically changing the position of the ECR region between the radical region 105 and the RIE region 106 and changing the ratio between times when the position of the ECR region respectively are set to be in the radical region 105 and the RIE region 106 are implemented as follows. Specifically, the direct current output from the DC coil current power supplies (also referred to as DC power supplies) 113a and 113b and applied to the magnetic field generation coils 112a and 112b is used to set to the center position of the ECR region. The alternating current output from the AC coil current power supply (also referred to as an AC power supply) 114 and applied to the magnetic field generation coil 112c is used to move the position of the ECR region up and down.

In the plasma processing apparatus 10 illustrated in FIG. 1, regarding the two types of the coil current power supplies, which are the DC coil current power supplies 113a and 113b and the AC coil current power supply 114, only the magnetic field generation coil 112c closest to the ion shielding plate 104 is connected to the AC coil current power supply 114, and the magnetic field generation coils 112a and 112b farther from the ion shielding plate 104 than the magnetic field generation coil 112c are connected to the DC coil current power supplies 113a and 113b.

This is for utilizing a property of a magnetic field generated by a coil, of having a higher intensity at a location closer to the coil, meaning that the current from the closest magnetic field generation coil 112c is highly effective for the intensity of the magnetic field near the ion shielding plate 104. Based on this property, the current from the magnetic field generation coil 112c closest to the ion shielding plate 104 may be changed to change the intensity of the magnetic field near the ion shielding plate 104 for moving the ECR region up and down with respect to the ion shielding plate 104.

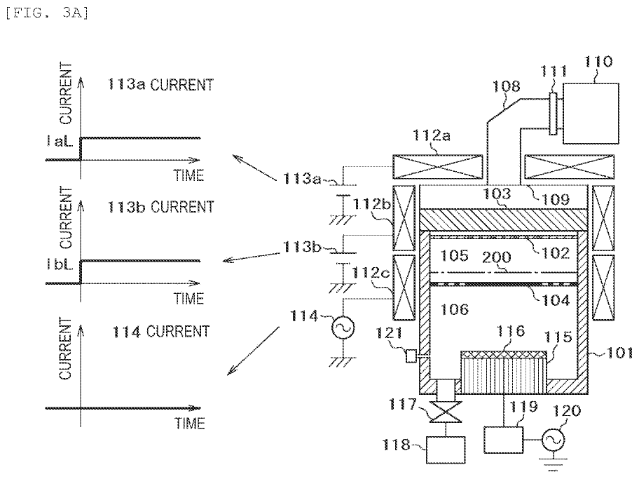

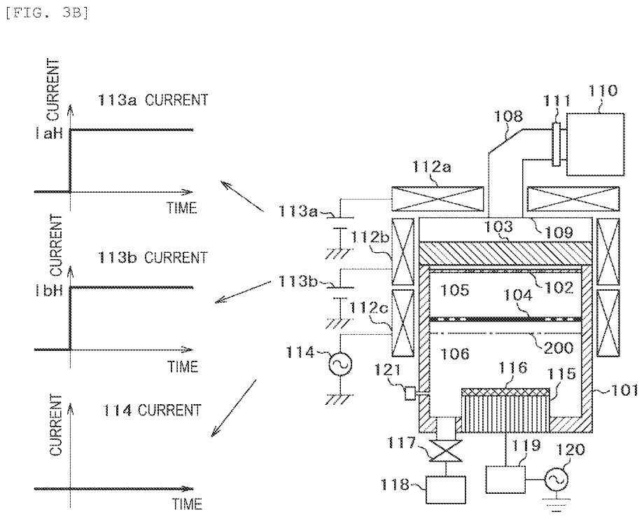

FIG. 3A and FIG. 3B illustrate an example where the position of the ECR region is set using the DC coil current power supplies 113a and 113b, with the output from the AC coil current power supply 114 being zero. In this example, the position of the ECR region may be regarded as the center position of the ECR region.

The magnetic field generated by the magnetic field generation coils 112a and 112b has intensity decreasing from the radical region 105 toward the RIE region 106. A magnetic field having a higher intensity than the magnetic field intensity in the ECR region is generated in an upper portion of the vacuum container 101 (or the processing chamber 100). Thus, a higher current leads to a larger movement of the ECR region toward the lower side in the vacuum container 101 (or the processing chamber 100).

Thus, as illustrated in FIG. 3A, a position 200 of the ECR region 200 achieved with low current (IaL, IbL) from the DC coil current power supplies 113a and 113b is in the radical region 105 more on the upper side than the ion shielding plate 104.

On the other hand, as illustrated in FIG. 3B, the position 200 of the ECR region achieved with high current (IaH>IaL, IbH>IbL) from the DC coil current power supplies 113a and 113b is in the RIE region 106 more on the lower side than the ion shielding plate 104.

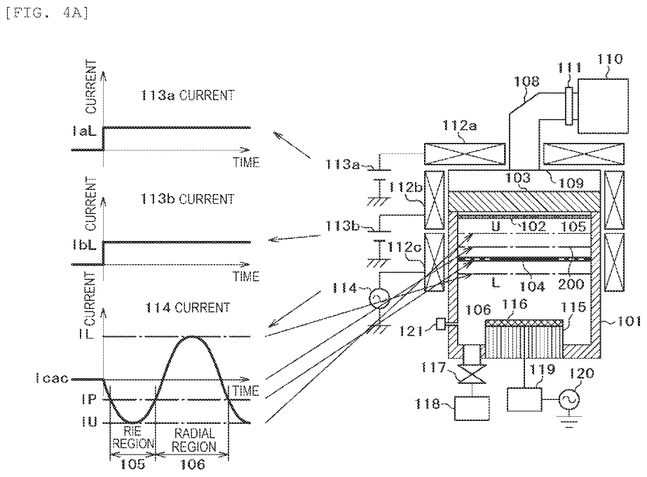

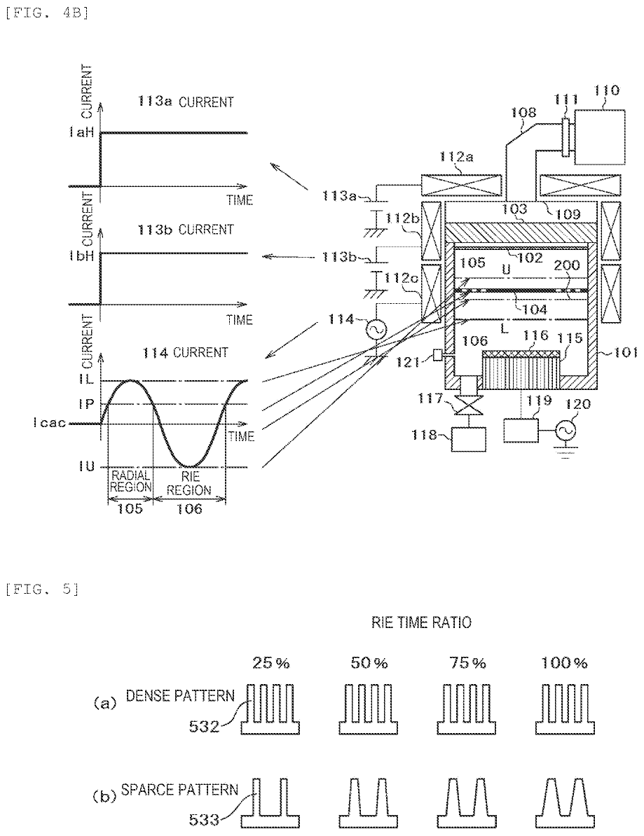

FIG. 4A and FIG. 4B illustrate an example where the position 200 of the ECR region initially set with the current IaL flowing in the magnetic field generation coil 112a and with the current IbL flowing in the magnetic field generation coil 112b, is moved up and down based on alternating current Icac flowing in the magnetic field generation coil 112c.

FIG. 4A and FIG. 4B illustrate an upper limit U and a lower limit L of the position 200 of the ECR region, the position of the ion shielding plate 104, and current values (IU (corresponding to the upper limit U), IL (corresponding to the lower limit L), and IP (corresponding to the position of the ion shielding plate 104)) corresponding to these positions.

Through an adjustment on the AC coil current power supply 114, the position of the ECR region can move to be below the ion shielding plate 104 and to be above the ion shielding plate 104 in the vacuum container 101 (or the processing chamber 100) when the alternating current Icac flowing in the magnetic field generation coil 112c is of a positive value and a negative value, respectively.

As illustrated in FIG. 4A, when the position 200 of the ECR region is changed with the alternating current Icac flowing in the magnetic field generation coil 112c and with the DC coil current power supply 113a making the relatively low current IaL flow in the magnetic field generation coil 112a and the DC coil current power supply 113b making the relatively low current IbL flow in the magnetic field generation coil 112b, the time when the position 200 of the ECR region is in the radical region 105 becomes longer than the time when the position is in the RIE region 106 in one period of the alternating current Icac.

On the other hand, as illustrated in FIG. 4B, when the position 200 of the ECR region is changed with the alternating current Icac flowing in the magnetic field generation coil 112c and with the DC coil current power supply 113a making the relatively high current IaH (IaH>IaL) flow in the magnetic field generation coil 112a and the DC coil current power supply 113b making the relatively high current IbH (IbH>IbL) flow in the magnetic field generation coil 112b, the time when the position 200 of the ECR region is in the RIE region 106 becomes longer than the time when the position is in the radical region 105 in one period of the alternating current Icac.

Thus, under the control by the control unit 130, the current made to flow in the magnetic field generation coil 112a by the DC coil current power supply 113a is switched between IaL and IaH and the current made to flow in the magnetic field generation coil 112b by the DC coil current power supply 113b is switched between IbL and IbH, in one period in synchronization with the period of the alternating current Icac flowing in the magnetic field generation coil 112c. As a result, the position 200 of the ECR region can be moved efficiently (within a relatively short period of time) between the radical region 105 and the RIE region 106 periodically, compared with a case without the switching of each direct current.

Specifically, with the control unit 130 controlling the DC coil current power supplies 113a and 113b and the AC power supply 114, the position 200 of the ECR region as a result of the interaction between microwaves and the magnetic field can be periodically changed. Within one period of the alternating current Icac made to flow in the magnetic field generation coil 112c by the AC coil current power supply 114, the position 200 of the ECR region can be moved between the radical region 105 above the ion shielding plate 104 and the RIE region 106 below the ion shielding plate 104.

In the present embodiment, the control unit 130 is used to implement repetition, for a predetermined number of times, of: a radical etching period in which the sample 116 is etched by isotropic etching mainly based on surface reaction using the radicals only, with the magnetic field adjusted to position the plasma generation region in the radical region 105 between the ion shielding plate 104 and the shower plate 102; and a RIE period in which the sample 116 is etched in the vertical direction, by anisotropic etching using both ions and radicals, with the magnetic field adjusted to position the plasma generation region in the RIE region 106 between the ion shielding plate 104 and the sample 116.

Note that mixed gas of NF₃/HBr is introduced into the processing chamber 100 for the plasma generation. By using this mixed gas, the following feature is achieved. Specifically, the pattern formed on the surface of the sample 116 is etched into a tapered shape by RIE, and the etching also progresses during the radical etching with the ion shielded in the same gas system.

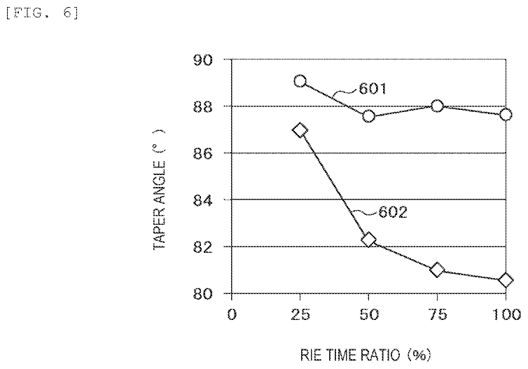

FIG. 5 is a schematic view of etching shapes indicating that the etching shapes of the sparse and of the dense portions can be independently controlled through the control on the RIE time ratio according to the present embodiment.

As illustrated in FIG. 5(a), the etching shape of a dense pattern portion 532 makes almost no change in response to a change in RIE time ratio from 25% to 100%. As illustrated in FIG. 5(b), the etching shape of a sparse pattern portion 533 largely change in response to the change in RIE time ratio from 25% to 100%.

Thus, it can be understood that the etching shapes of the sparse pattern portion and of the dense pattern portion can be independently controlled, by controlling the RIE time ratio.

FIG. 6 is a graph indicating that the taper angle can be made equal between the sparse and the dense portions, through the control on the RIE time ratio according to the present embodiment, where 601 represents the dependency, on the RIE time ratio, of the taper angle of the dense pattern corresponding to the dense pattern portion 532 in FIGS. 5, and 602 represents the dependency, on the RIE time ratio, of the taper angle of the sparse pattern corresponding to the sparse pattern portion 533 in FIG. 5.

FIG. 6 is a graph indicating the taper angle measured in the schematic view in FIG. 5. The dense pattern portion has the taper angle 601 making almost no change in response to a change in the RIE time ratio, whereas in response to a decrease in the RIE time ratio, the dense pattern portion has the taper angle 602 approaching 90 degrees, that is, the taper angle 601 of the dense pattern portion, and thus approaches a vertical shape.

It can be understood from FIG. 6 that the RIE time ratio is preferably set to be lower than 50%, to make the taper angle equal between the sparse and the dense pattern portions after the etching. Specifically, the control unit 130 preferably controls the electromagnetic wave generating power supply 110, the DC coil current power supplies 113a and 113b, and the AC coil current power supply 114, to control the RIE time ratio (the ratio of the RIE processing time to the total processing time of the RIE and the radical etching) to be lower than 50%, resulting in the RIE being performed for a shorter period of time than the radical etching.

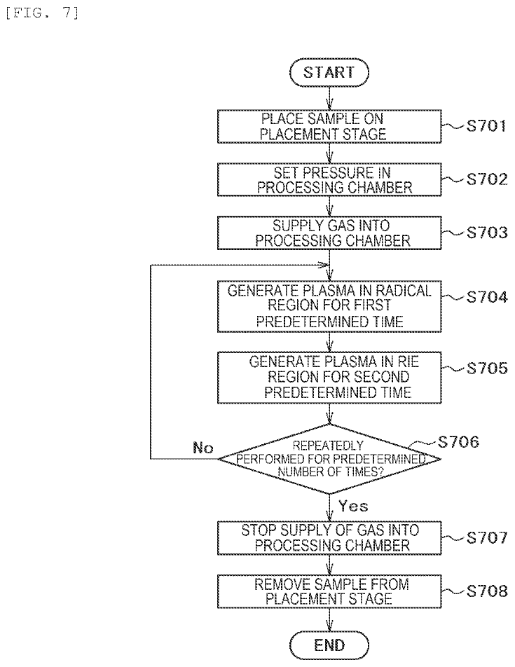

Next, a plasma processing method using the plasma processing apparatus 10 will be described with reference to a flowchart in FIG. 7.

First of all, a step of placing the sample 116, as a sample for forming a Gate ALL Around (GAA) structure on the surface of the semiconductor substrate, on the substrate electrode 115 in the processing chamber 100 is performed (S701).

Next, a step of controlling the pressure in the processing chamber 100 is performed using the pressure adjustment valve 117 and the vacuum exhaust device 118 (S702).

Next, a step of supplying etching gas generated by mixing a plurality of gases for performing the plasma etching processing from the gas supply device 107 to a region in the processing chamber 100 between the shower plate 102 and the dielectric window 103 through the gas supply pipe 1071 is performed (S703).

Next, as illustrated in FIG. 3A, the electromagnetic wave generating power supply 110, the DC coil current power supplies 113a and 113b, and the AC coil current power supply 114 are operated to set the position 200 of the ECR region to be in the radical region 105 on the upper side of the ion shielding plate 104, and the plasma is generated in the radical region 105 for a first predetermined time (S704). In this state, the radicals generated in the radical region 105 are supplied to the RIE region 106 side through multiple through holes 1041 formed in the circumference area of the ion shielding plate 104, whereby the plasma processing is performed on the sample 116 through radical etching (isotropic etching).

Next, as illustrated in FIG. 3B, the electromagnetic wave generating power supply 110, the DC coil current power supplies 113a and 113b, and the AC coil current power supply 114 are operated to set the position 200 of the ECR region to be in the RIE region 106 on the lower side of the ion shielding plate 104, and the plasma is generated in the RIE region 106 for a second predetermined time (S705). Since there is no shield between the plasma generated in the ECR region and the sample 116, both ions and radicals from the plasma are supplied to the sample 116, whereby the plasma processing is performed on the sample 116 through RIE (anisotropic etching).

The processing in step S704 and the processing in step S705 are alternately repeated for a predetermined number of times (S706).

After the processing in step S704 and the processing in step S705 have been alternately repeated for a predetermined number of times (Yes in S706), the operation of the electromagnetic wave generating power supply 110, the DC coil current power supplies 113a and 113b, and the AC coil current power supply 114 is stopped, and the supply of the etching gas from the gas supply device 107 is stopped (S707).

Next, the sample 116 placed on the substrate electrode 115 is removed (S708), and the series of processes ends.

For the radical etching (isotropic etching) in step S704 and the RIE (anisotropic etching) in step S705, the control unit 130 may perform control to switch the radio-frequency power supplied from the electromagnetic wave generating power supply 110 to a value suitable for each of these processes.

According to the present embodiment, the following effects can be achieved.

1) The anisotropic etching process for which the ions and the radicals are supplied, and the isotropic etching process for which only the radicals are supplied can both be implemented with one plasma processing apparatus 10.

2) A technique can be provided that enables more direct control on a density ratio between ions and radicals, for the anisotropic etching process for which the ions and the radicals are supplied.

3) For the anisotropic etching process with the radicals and the ions supplied, the density of the radicals supplied onto the surface of the sample (semiconductor substrate) can be highly precisely controlled, whereby highly-precise plasma etching technique can be provided.

4) The etching shapes of the sparse and of the dense pattern portions in a single wafer can be independently controlled, whereby the the sparse and the dense pattern portions can be uniformly etched.

In the present embodiment, three magnetic field generation coils 112a, 112b, and 112c are used, but the number of coils is not limited to this. When there are a plurality of magnetic field generation coils, the coils may be connected to the AC coil current power supply one by one from the one closest to the ion shielding plate 104, while connecting the AC coil current power supply to the remaining magnetic field generation coils.

Generally, when the magnetic field in a plasma processing chamber is changed using a radio-frequency power supply, inductive current at a radio-frequency flows into the plasma. As a result, inductive coupled plasma may be generated with the generation of plasma maintained by the inductive current. The plasma thus generated is different from that generated by ECR, meaning that the plasma generation position cannot be controlled through control on the ECR region position. In view of this, a frequency of 1 kHz or lower is preferably used for the frequency of the AC coil current power supply, so as not to generate the inductive coupled plasma.

In FIG. 4A and FIG. 4B, a sine wave is illustrated as the output from the AC coil current power supply 114, but the output is not limited to sine waves. The AC power supply may be capable of outputting periodically changing waveforms other than sine waves, such as rectangular waves.

### Modification

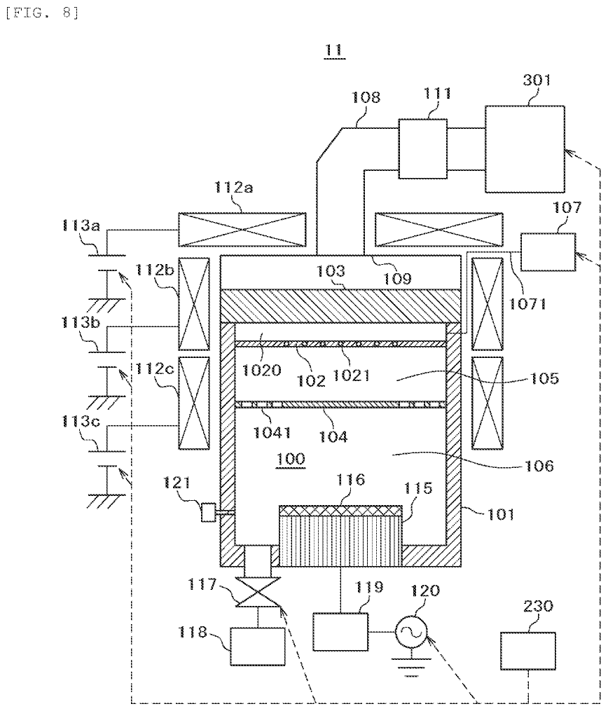

FIG. 8 is a vertical cross-sectional view schematically illustrating an overall configuration of a plasma processing apparatus 11 according to a modification of Embodiment 1. The current applied to the magnetic field generation coils 112a to 112c is changed to control the ECR region position control in Embodiment 1, in the present modification, the frequency of the electromagnetic wave generating power supply is switched to control the ECR region position control.

Components that are the same as those in the plasma processing apparatus 10 described in Embodiment 1 are denoted by the same reference numerals. The configuration of the present modification is obtained by replacing the electromagnetic wave generating power supply (radio-frequency power supply) 110 described in Embodiment 1 with a variable frequency electromagnetic wave generating power supply (also referred to as a variable frequency radio-frequency power supply) 301, replacing the control unit 130 in Embodiment 1 with a control unit 230, and replacing the AC coil current power supply 114 in Embodiment 1 with a DC coil current power supply 113c.

Electromagnetic waves oscillated from the variable frequency electromagnetic wave generating power supply 301 are transmitted through the electromagnetic wave matching box 111. Using the electromagnetic waves propagated from the waveguide 108, a standing wave under a certain mode is formed in the cavity resonator 109 of the processing chamber 100.

In the present modification, the frequency range of the electromagnetic waves at the variable frequency oscillated from the variable frequency electromagnetic wave generating power supply 301 is not particularly limited, and the waves are microwaves at 1.80 GHz to 2.45 GHz in the present modification. The magnetic field generation coils 112a, 112b, and 112c are provided in the outer circumference portion of the processing chamber 100. The DC coil current power supplies 113a, 113b, and 113c are connected to the magnetic field generation coils 112a, 112b, and 112c to control the current therein. The magnetic field generation coils 112a, 112b, and 112c and the DC coil current power supplies 113a, 113b, and 113c may be referred to as a magnetic field forming mechanism.

Plasma is generated in the processing chamber 100 through electron cyclotron resonance (ECR) between the power oscillated by the variable frequency electromagnetic wave generating power supply 301 and the magnetic field formed by the magnetic field generation coils 112a, 112b, and 112c.

To cause ECR with the electromagnetic waves at 1.80 GHz to 2.45 GHz to generate the plasma, a magnetic field of 0.0643 T to 0.0875 T is required. A region in the processing chamber 100 where the magnetic field has such an intensity that causes resonance corresponding to each frequency is referred to as an ECR region. To generate the high-intensity magnetic field, the magnetic field generation coils 112a, 112b, and 112c with self-inductance of 100 to 1000 mH are used, and the DC coil current power supplies 113a, 113b, and 113c are capable of supplying current of about 10 to 60 A.

The control unit 230 controls the values of current supplied from the plurality of DC coil current power supplies 113a to 113c to the magnetic field generation coils 112a, 112b, and 112c respectively connected thereto, whereby the plasma generation position can be moved with respect to the sample 116 with the position of the ECR region in the processing chamber 100 controlled precisely.

The magnetic field generation coils 112a and 112b are positioned more on the upper side than the ion shielding plate 104, and thus the intensity of the magnetic field generated by these magnetic field generation coils 112a and 112b is higher in the radical region 105 close to the magnetic field generation coils 112a and 112b than in the RIE region 106.

This is because, for propagating the electromagnetic waves to the ECR region where the plasma is generated, the magnetic field is preferably set to have the intensity decreasing the ECR region from the incident direction of the electromagnetic waves. Thus, the magnetic field increases in the direction of the waveguide 108 as viewed from the ECR region, that is, in the direction of the radical region 105 as viewed from the RIE region 106.

As described in Embodiment 1, the processing chamber 100 has the ion shielding plate 104 provided between the shower plate 102 and the sample 116, and is divided into two regions that are the radical region 105 more on the upper side than the ion shielding plate 104 and the RIE region 106 more on the lower side than the ion shielding plate 104.

When plasma is generated with the position 200 of the ECR region set to be in the radical region 105, since the ion shielding plate 104 is disposed between the sample 116 and the plasma, the ions from the plasma do not reach the sample 116 due to the effect of the ion shielding plate 104 and only the radicals are supplied. Thus, the sample 116 is plasma-processed through the radical etching.

When plasma is generated with the position 200 of the ECR region set to be in the RIE region 106, since there is no shield between the plasma and the sample 116, both ions and radicals from the plasma are supplied to the sample 116, and the sample 116 is plasma-processed through RIE (anisotropic etching).

The gas supply device 107, the pressure adjustment valve 117, the variable frequency electromagnetic wave generating power supply 301, the DC coil current power supply 113, and the radio-frequency power supply 120 are connected to the control unit 230 that controls the plasma processing apparatus in accordance with process conditions. For process conditions including a plurality of plasma processing steps, the control unit 230 controls each of apparatus parameters sequentially according to the processing steps to perform etching processing on the sample 116.

In the present embodiment, when the position of the ECR region is set to be on the upper side of the ion shielding plate 104, the radicals are mainly supplied to the sample 116, and when the position of the ECR region is set to be on the lower side of the ion shielding plate 104, the radicals and the ions are both supplied to the sample 116. Based on this, the position of the ECR region is set to be in these two regions (105 and 106) periodically, whereby the reactive ion etching is performed with the density ratio between the ions and the radicals controlled.

With normal RIE, the plasma is generated in a region corresponding to the RIE region 106 over the entire processing time. On the other hand, with the plasma generated in the RIE region 106 and also in the radical region 105, there can be a time when the only radicals are supplied to the sample 116, in addition to a time when the ions and the radicals are both supplied to the sample 116.

With the plasma generation region switched periodically between the RIE region 106 and the radical region 105, the RIE as a whole can be performed with the densities of ions and the radicals supplied to the sample 116 respectively reduced and increased. The ions are supplied to the sample 116 only during the time when the plasma is generated in the RIE region 106. Thus, the amount of ions supplied to the sample 116 is proportional to the ratio of time when the position of the ECR region is set to be in the RIE region 106 in one period of periodical switching of the position.

With the position of the ECR region set to be in the RIE region 106 for a longer period of time, the ratio of the ions increases. With the position of the ECR region set to be in the radical region 105 for a longer period of time, the ratio of the radical increases. Thus, the density ratio between the ions and the radicals can be changed based on a ratio between the times during which the position of the ECR region is respectively set to be in the RIE region 106 and is set to be in the radical region in one period.

The periodical control on the position of the ECR region and the change in the times during which the position of the ECR region are respectively set to be in the radical region 105 and the RIE region 106 can be implemented as follows. Specifically, the current output from the DC coil current power supplies 113a, 113b, and 113c is used to set the position of the ECR region corresponding to the center frequency of a frequency range of the variable frequency electromagnetic wave generating power supply 301, that is, to a center frequency 2.13 GHz in a case of a range from 1.80 GHz to 2.45 GHz. The position of the ECR region is moved up and down by changing the output frequency of the variable frequency electromagnetic wave generating power supply 301 for the magnetic field.

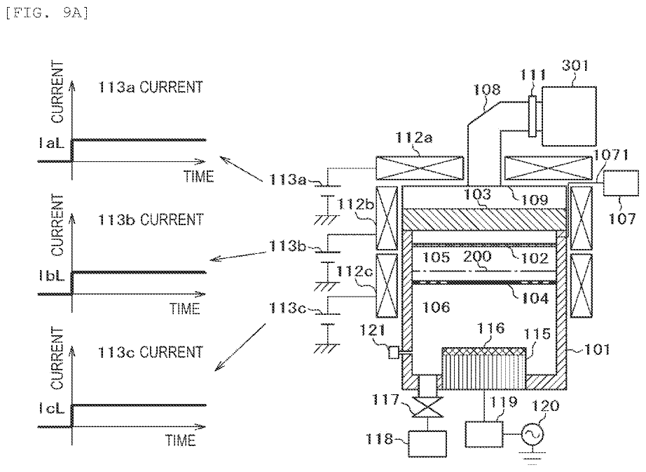

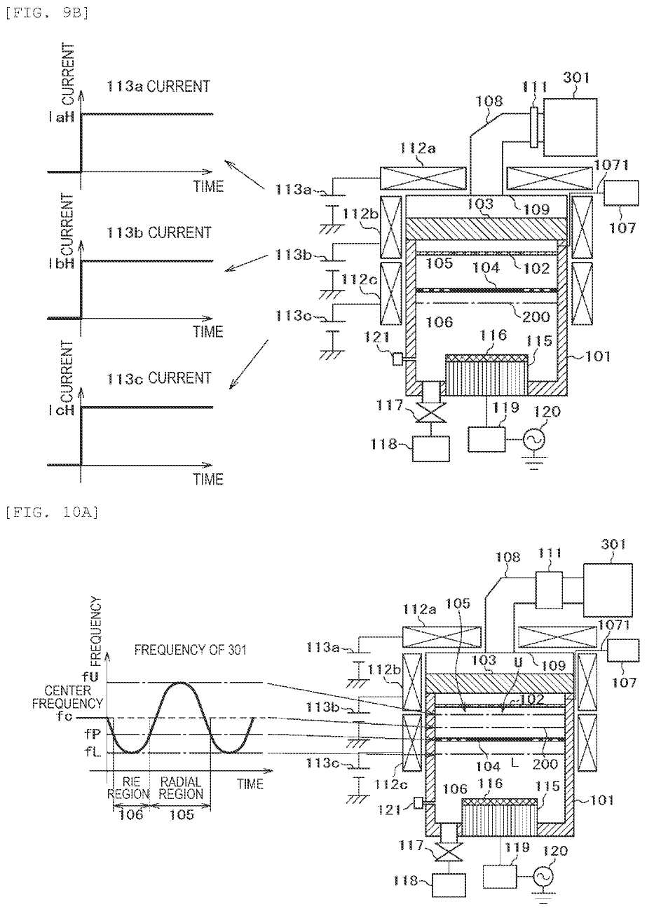

FIG. 9A and FIG. 9B illustrate an example where the DC coil current power supplies 113a, 113b, and 113c set the position 200 of the ECR region corresponding to the center frequency. The position of the ECR region can be regarded as the center position of the ECR region in this example.

The magnetic field generated by the magnetic field generation coils 112a, 112b, and 112c has intensity decreasing from the radical region 105 toward the RIE region 106. A magnetic field having a higher intensity than the magnetic field intensity in the ECR region is generated in an upper portion of the vacuum container 101. Thus, a higher current leads to a larger movement of the ECR region toward the lower side in the vacuum container 101.

Thus, as illustrated in FIG. 9A, the position 200 of the ECR region achieved with low current (IaL, IbL, IcL) from the DC coil current power supplies 113a, 113b, and 113c is in the radical region 105 more on the upper side than the ion shielding plate 104. As illustrated in FIG. 9B, the position 200 of the ECR region achieved with high current (IaH>IaL, IbH>IbL, IcH>IcL) from the DC coil current power supplies 113a, 113b, and 113c is in the RIE region 106 more on the lower side than the ion shielding plate 104.

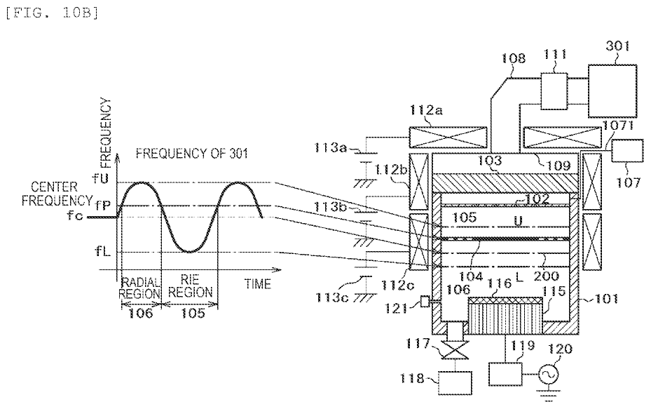

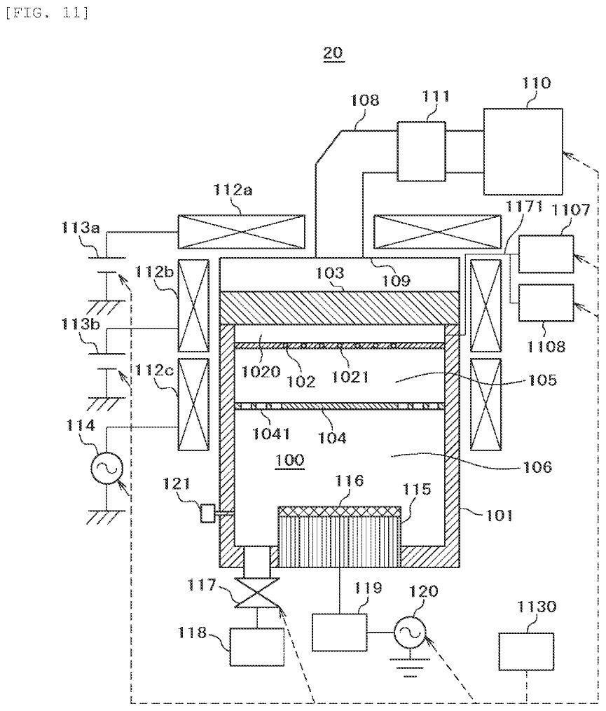

FIG. 10A and FIG. 10B illustrate an example where the position 200 of the ECR region set with the magnetic field generation coils 112a, 112b, and 112c, is moved up and down based on the frequency of the variable frequency electromagnetic wave generating power supply 301.

FIG. 10A Illustrates frequencies (fU, fL, fP) respectively corresponding to the upper limit U and the lower limit L of the position 200 of the ECR region and the position of the ion shielding plate 104. When the frequency is lower than a center frequency fc, the magnetic field intensity required for resonation is also low. Thus, the position of the ECR region moves toward a lower side in the vacuum container 101 when the frequency is low, and is moves toward an upper side when the frequency is higher than the center frequency. As illustrated in FIG. 10A, when the position 200 of the ECR region corresponding to the center frequency fc is set to be in the radical region 105 by the DC coil current power supplies 113a, 113b, and 113c, the time when the position of the ECR region is set to be in the radical region 105 is longer than the time when the position is set to be in the RIE region 106.

As illustrated in FIG. 10B, when the position of the ECR region corresponding to the center frequency fc is set to be in the RIE region 106 by the DC coil current power supplies 113a, 113b, and 113c, the time when the position is set to be in the RIE region 106 is longer than the time when the position is set to be in the radical region 105.

With the frequency of the variable frequency electromagnetic wave generating power supply 301 periodically changed, the position of the ECR region can be moved to be in the radical region 105 and in the RIE region 106 periodically, without changing the magnetic field intensity. Specifically, with the control unit 230 controlling the variable frequency electromagnetic wave generating power supply 301, the position 200 of the ECR region as a result of the interaction between microwaves and the magnetic field can be periodically changed. Thus, within one period, the position 200 of the ECR region can be moved from the upper side of the ion shielding plate 104 to the lower side of the ion shielding plate 104, or from the lower side of the ion shielding plate 104 to the upper side of the ion shielding plate 104.

A plasma processing method using the plasma processing apparatus 11 according to the present modification is the same as the process flow described in Embodiment 1 with reference to FIG. 7, and thus the detailed description thereof will be omitted. Still, the present modification is different from Embodiment 1 in that the ECR region is changed by periodically changing the frequency of the variable frequency electromagnetic wave generating power supply 301 in step S704 of generating the plasma in the radical region for the first predetermined time, and in step S705 of generating the plasma in the RIE region for the second predetermined time.

According to the resent modification, a technique can be provided that enables more direct control on the density ratio between the ions and radicals, for the anisotropic etching process for which the ions and the radicals are supplied.

As a combination of the configuration described in Embodiment 1 and the configuration described in the above modification, a configuration may be employed in which the DC coil current power supply 113c is changed to the AC coil current power supply 114 described in Embodiment 1 in the plasma processing apparatus 11 described in the modification. In this case, the frequency of the variable frequency electromagnetic wave generating power supply 301 and the frequency of the AC coil current power supply 114 need to be set to achieve a desired density ratio between ions and radicals for the anisotropic etching process.

Furthermore, a configuration may be employed in which the variable frequency electromagnetic wave generating power supply 301 and the electromagnetic wave generating power supply 110 of Embodiment 1 are both provided in the plasma processing apparatus 11 described in the modification. In this case, when the isotropic etching is performed, the electromagnetic wave generating power supply 110 is operated instead of the variable frequency electromagnetic wave generating power supply 301 in the configuration illustrated in FIG. 9A. When the anisotropic etching is performed, the electromagnetic wave generating power supply 110 is operated instead of the variable frequency electromagnetic wave generating power supply 301 in the configuration illustrated in FIG. 9B. On the other hand, when the anisotropic etching is performed with the density ratio between ions and radicals highly precisely controlled, the variable frequency electromagnetic wave generating power supply 301 is operated as illustrated in FIG. 10A and FIG. 10B.

With this configuration, the anisotropic etching process for which the ions and the radicals are supplied, and the isotropic etching process for which only the radicals are supplied can be implemented with one plasma processing apparatus 10.

### Embodiment 2

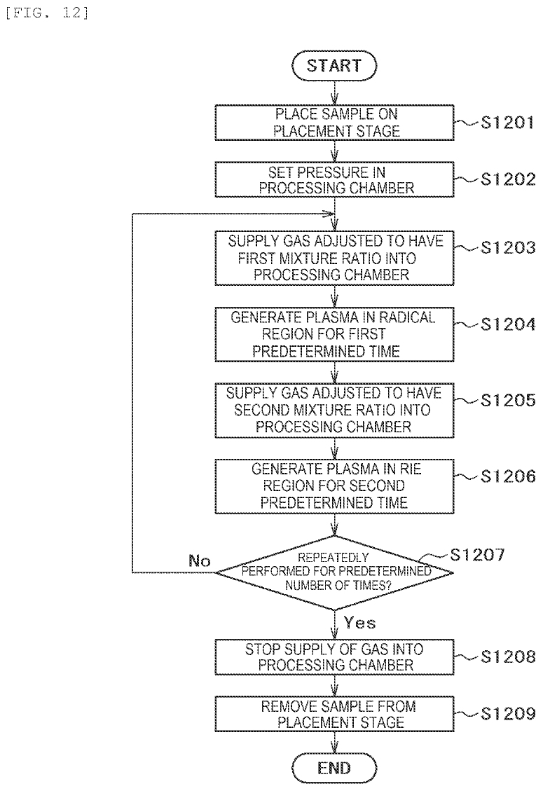

Embodiment 2 of the present invention will be described with reference to FIG. 11 and FIG. 12. In Embodiment 1, the etching shapes of the sparse and of the dense pattern portions formed on the surface of a sample can be independently controlled through switching of the ECR region as illustrated in the processing flow charge in FIG. 7. In a configuration of the present embodiment, additionally, the mixture ratio of the mixed gas is also switched in accordance with the switching of the ECR region.

A configuration of a plasma processing apparatus 20 according to the present embodiment illustrated in FIG. 11 is different from the configuration of the plasma processing apparatus 10 described in Embodiment 1 with reference to FIG. 1 in the configuration of the gas supply device 107 and the control unit 130. The other components are the same as Embodiment 1 and thus will be denoted by the same reference numerals, and the detailed description thereof will be omitted.

The plasma processing apparatus 20 with the configuration illustrated in FIG. 11 includes gas supply devices 1107 and 1108. A control device 1130 adjusts the mixture ratio between gases supplied from the gas supply devices 1107 and 1108. Thus, the mixed gas with the mixture ratio adjusted in accordance with steps is supplied from the gas supply pipe 1171 to a region 1020 between the shower plate 102 and the dielectric window 103.

As in Embodiment 1 or the modification of Embodiment 1, the etching processing mainly based on the radical reaction and the etching processing using ions and radicals are alternately performed, with the ECR region switched between the radical region above the ion shielding plate 104 and the RIE region 106 below the ion shielding plate 104 during the etching processing.

The present embodiment is different from Embodiment 1 in that the mixture ratio between a plurality of gases forming the mixed gas (such as NF₃/HBr) supplied to the processing chamber 100 is switched between the etching processing mainly based on the radical reaction and the etching processing using ions and radicals.

Specifically, in the present embodiment, the control device 1130 controls the gas supply devices 1107 and 1108 to switch the mixture ratio of HBr gas to NF₃ gas in the step of the etching processing using ions and radicals, from that in the step of the etching processing mainly based on the radical reaction.

A flow of the etching processing according to the present embodiment will be described with reference to FIG. 12. First of all, a step of placing the sample 116, as a sample for forming a GAA structure on the surface of the semiconductor substrate, on the substrate electrode 115 in the processing chamber 100 is performed (S1201).

Next, a step of controlling the pressure in the processing chamber 100 is performed with the vacuum exhaust device 118 discharging the air inside the processing chamber 100 through the pressure adjustment valve 117 is performed (S1202).

Next, a step of supplying, to a region between shower plate 102 and the dielectric window 103 in the processing chamber 100 from the gas supply pipe 1171, etching gas, for performing the plasma etching processing supplied from the gas supply device 1107 and 1108, adjusted to have a first mixture ratio suitable for the radical etching processing is performed (S1203).

Next, as illustrated in FIG. 3A, the electromagnetic wave generating power supply 110, the DC coil current power supply 113, and the AC coil current power supply 114 are operated to set the position 200 of the ECR region to be in the radical region 105 on the upper side of the ion shielding plate 104, and the plasma is generated in the radical region 105 for the first predetermined time (S1204). In this state, the radicals generated in the radical region 105 are supplied toward the RIE region 106 side through the multiple through holes 1041 formed in the circumference area of the ion shielding plate 104, whereby the plasma processing is performed on the sample 116 through radical etching (isotropic etching).

Next, a step of supplying, to the region between shower plate 102 and the dielectric window 103 in the processing chamber 100 from the gas supply pipe 1171, etching gas, for performing the plasma etching processing supplied from the gas supply device 1107 and 1108, adjusted to have a second mixture ratio suitable for the RIE (anisotropic etching) is performed (S1205).

Next, as illustrated in FIG. 3B, the electromagnetic wave generating power supply 110, the DC coil current power supply 113, and the AC coil current power supply 114 are operated to set the position 200 of the ECR region to be in the RIE region 106 on the lower side of the ion shielding plate 104, and the plasma is generated in the RIE region 106 for a second predetermined time (S1206). Since there is no shield between the plasma generated in the ECR region and the sample 116, both ions and radicals from the plasma are supplied to the sample 116, whereby the plasma processing is performed on the sample 116 through RIE (anisotropic etching).

The processing in step S1203 to step S1206 are repeated for a predetermined number of times (S1207).

After the processing in step S1203 to step S1206 have been repeated for a predetermined number of times (Yes in S1207), the operation of the electromagnetic wave generating power supply 110, the DC coil current power supply 113, and the AC coil current power supply 114 is stopped, and the supply of the etching gas from the gas supply devices 1107 and 1108 is stopped (S1208).

Next, the sample 116 placed on the substrate electrode 115 is removed (S1209), and the series of processes ends.

For step S1204 for the radical etching (isotropic etching) and step S1206 for the RIE (anisotropic etching), the control device 1130 may perform control to switch the radio-frequency power supplied from the electromagnetic wave generating power supply 110 to a value suitable for each of these processes.

According to the present embodiment, in addition to the effect described in Embodiment 1, the etching shapes of the sparse and the dense pattern portions in a single wafer can be independently and efficiently controlled, whereby the sparse and the dense pattern portions can be uniformly etched.

Also in the present embodiment, the configuration as described in the modification of Embodiment 1 can be applied.

The embodiments above are described in detail for the sake of better understanding of the present invention. The present invention is not limited to the embodiments above. It is a matter of course that various changes can be made.

### Reference Signs List

10, 11, 20: plasma processing apparatus

100: processing chamber

101: vacuum container

102: shower plate

103: dielectric window

104: ion shielding plate

1041: through hole

105: radical region

106: RIE region

107, 1107, 1108: gas supply device

108: waveguide

109: cavity resonator

110: electromagnetic wave generating power supply

111: electromagnetic wave matching box

112a, 112b, 112c: magnetic field generation coil

113a, 113b, 113c: DC coil current power supply

114: AC coil current power supply

115: substrate electrode

116: sample

117: pressure adjustment valve

118: vacuum exhaust device

119: radio-frequency matching box

120: radio-frequency power supply

130, 230: control unit

200: position of ECR region

301: variable frequency electromagnetic wave generating power supply

1071, 1171: gas supply pipe

1. A plasma processing method characterized by comprising:
a first step of performing reactive ion etching using gas resulting in a tapered shape; and
a second step of performing radical etching, characterized in that
the first step and the second step are alternately repeated for a predetermined number of times, and a time of the first step is shorter than a time of the second step.

2. The plasma processing method according to claim 1, characterized in that the gas is a mixed gas of NF₃ gas and HBr gas.

3. The plasma processing method according to claim 1, characterized in that the second step includes generating the plasma using gas that is the same as the gas.

4. The plasma processing method according to claim 1, characterized in that a ratio of a time of the first step to a time of the second step is lower than 50%.

5. The plasma processing method according to claim 1, characterized in that the first step and the second step are alternately repeated, through control on a power supply generating a magnetic field, with which a position of a region of electron cyclotron resonance generated as a result of interaction between microwaves and the magnetic field is periodically changed to be above and below a shielding plate configured to shield ions otherwise being incident on a sample placed on a sample stage.

6. The plasma processing method according to claim 5, characterized in that the gas is a mixed gas of NF₃ gas and HBr gas.

7. The plasma processing method according to claim 6, characterized in that a ratio of a time of the first step to a time of the second step is lower than 50%.

8. The plasma processing method according to claim 1, characterized in that
the gas is mixed gas, and
a ratio between flow rates of gases forming the mixed gas in the first step is different from the ratio between the flow rates of the gases forming the mixed gas in the second step.
